(19) United States
(12) Patent Application Publication
(10) Pub. No.: US 2010/0289037 A1
(43) Pub. Date: Nov. 18, 2010

(54) SEMICONDUCTOR DEVICE, MANUFACTURING METHOD THEREOF AND DISPLAY DEVICE

(76) Inventors: Shin Matsumoto, Osaka (JP); Yutaka Takafuji, Osaka (JP); Yasumori Fukushima, Osaka (JP); kenshi Tada, Osaka (JP)

Correspondence Address: NIXON & VANDERHYE, PC, 901 NORTH GLEBE ROAD, 11TH FLOOR, ARLINGTON, VA, 22203, US

(21) Appl. No.: 12/812,162

(22) PCT Filed: Oct. 10, 2008
(86) PCT No.: PCT/JP2008/068493

§ 371 Date: Jul. 8, 2010

(30) Foreign Application Priority Data
Jan. 15, 2008 (JP) 2008-006168

(51) Int. Cl. H01L 33/00; H01L 27/092; H01L 21/336; H01L 29/786

(52) U.S. Cl. 257/88; 257/351; 438/151; 257/347; 257/E33.053; 257/E29.286; 257/E21.415; 257/E21.704; 257/E27.062

(57) ABSTRACT

The present invention provides a semiconductor device having a plurality of MOS transistors with controllable threshold values in the same face and easy to manufacture, a manufacturing method thereof and a display device. The invention is a semiconductor device having a plurality of MOS transistors in the same face each having a structure formed by stacking a semiconductor active layer, a gate insulator, and a gate electrode, wherein the semiconductor device includes: an insulating layer stacked on a side opposite to a gate electrode side of the semiconductor active layer; and a conductive electrode stacked on a side opposite to a semiconductor active layer side of the insulating layer and extending over at least two of the plurality of MOS transistors.

### TECHNICAL FIELD

The present invention relates to a semiconductor device, a manufacturing method thereof, and a display device. More particularly, the invention relates a semiconductor device suitable for display devices such as a liquid crystal display device and an organic electroluminescent display device, a manufacturing method thereof, and a display device.

### BACKGROUND ART

Semiconductor devices are electronic devices each equipped with active elements utilizing electric characteristics of semiconductors and have been used widely for, for example, audio appliances, communication appliances, computers, and domestic electric appliances. Particularly, a semiconductor device equipped with a three-terminal active element such as a thin film transistor (hereinafter, also referred to as TFT), a MOS (Metal Oxide Semiconductor) transistor, or the like is employed as switching elements installed for respective pixels, a control circuit for controlling respective pixels, or the like in display devices such as an active matrix liquid crystal display device (hereinafter, also referred to as “liquid crystal display”), an organic electroluminescent display device (hereinafter, also referred to as “organic EL display”).

In recent years, as a technique relevant to a display device, a liquid crystal display, so-called monolithic liquid crystal display (hereinafter, also referred to as “system liquid crystal”) in which peripheral driver circuits such as a driving circuit and a control circuit are united with pixel parts has drawn attraction. With respect to a semiconductor device to be used for such a system liquid crystal, since switching elements of pixel parts and peripheral driver circuits can be simultaneously formed on a single substrate, the number of components can be considerably lessened and also the number of assembly steps and the number of inspection steps of the liquid crystal display can be lessened and it can save the production cost and can improve reliability.

Further, with respect to a display device such as a liquid crystal display device, low power consumption, and performance advancements such as higher resolution and higher speed of image display have been strongly desired. Moreover, it has been also required to save the installation space for peripheral drivers of the system liquid crystal. Therefore, further miniaturization of respective elements is strongly required for the semiconductor device to be used for a display device and a design rule in sub-micron level, that is, micro-pattern precision in integrated circuit level, is needed for peripheral driver circuits in order to form a large number of elements in a limited surface area. Furthermore, since it is also required to heighten the mobility of a carrier in a semiconductor active layer for semiconductor elements constituting the peripheral driver circuits, miniaturization of elements is necessary to meet the requirement.

However, in a conventional manufacturing process of forming a semiconductor device directly on a glass substrate, since the heat resistance of the glass substrate is insufficient, there may be a fear that strains are formed in the glass substrate during a heat treatment step in the manufacturing process and it sometimes leads to impossibility of forming desired circuit patterns in sub-micron level. Further, enlargement of the size of the glass substrate to be used for manufacturing a liquid crystal display device such as a system liquid crystal or the like has been advanced and accordingly, strains tend to be more easily formed in the surface of the glass substrate during the manufacturing process.

Under this circumstance, a technique of transferring a driver integrated circuit to a substrate of a liquid crystal display using an integrated circuit chip in which the driver integrated circuit is formed on an SOI (Silicon On Insulator) substrate which has a single crystal silicon layer on an insulating layer. The parasite capacity can be reduced and simultaneously the insulation resistance can be increased by forming a device such as a transistor or the like on the SOI substrate and therefore, performance advancements and integration of the device are made possible. Consequently, a display device equipped with peripheral driver circuits constituted by highly advanced and integrated devices can be provided.

With respect to the SOI substrate, in terms of increase of the operation speed of a device and at the same time reduction of the parasite capacity, it is preferable to make the film thickness of the single crystal silicon layer thin. In general, as a method for producing the SOI substrate, for example, methods employing mechanical polishing, chemical mechanical polishing and porous silicon have been known. Among the methods, the smart cut method including ion-injecting hydrogen in a semiconductor substrate, sticking another substrate, carrying out heat treatment to separate the semiconductor substrate along the hydrogen injection layer, and thus carrying out transfer to the latter substrate is proposed (e.g., see Non-patent Documents 1 and 2). This technique makes it possible to obtain the SOI substrate having a single crystal silicon layer formed on the surface of an insulating layer. Formation of a MOS transistor on a substrate with such a structure reduces the parasite capacity and simultaneously increases the insulation resistance and therefore, performance advancements and integration of the device are made possible.

As a technique of saving electric power consumption in stand-by mode of a semiconductor device, there is disclosed a semiconductor device in which gate electrodes are formed in both sides of a semiconductor thin film and theoretical signals are applied to a first gate electrode and threshold value control signals are applied to a second gate electrode (e.g., see Patent Document 1). Further, as a technique of remarkably improving the operation speed and retention characteristic of a thin film transistor, there is disclosed a thin film transistor circuit in which a conductive electrode is arranged so as to be opposite to a gate electrode while keeping a channel region of an active layer interposed therebetween (e.g., see Patent Document 2). Furthermore, as a technique relevant to the SOI substrate, there are disclosed a method of manufacturing a semiconductor integrated circuit involving a step of forming a gate electrode in the rear face side of a semiconductor layer with an insulating film interposed therebetween (e.g., see Patent document 3), and a semiconductor device having an additional gate electrode formed in the surface insulating film in such a manner that the gate electrode is aligned in a channel formation region of a transistor element (e.g., see Patent Document 4).

[Non-patent Document 1] M. Bruel, “Silicon on insulator material technology,” Electronics Letters, USA, Vol. 31, No. 14, p. 1201-1202, (1995) [Non-patent Document 2] Michel Bruel, other three persons, “Smart Cut: A New Silicon On insulator Material Technology Based on Hydrogen Implantation and Wafer Bonding,” Japanese Journal of Applied Physics, Japan, Vol. 36, No. 3B, p. 1636-1641, (1997)

[Patent Document 1] Japanese Kokai Publication 2004-319999

[Patent Document 2] Japanese Kokai Publication Hei 9-73102

[Patent Document 3] Japanese Kokai Publication 2005-183622

[Patent Document 4] Japanese Kokai Publication 2001-77377

### DISCLOSURE OF THE INVENTION

However, in such a method as the smart cut method involving transferring an integrated circuit by ion-injecting a substance containing hydrogen for separation in a semiconductor substrate and separating the semiconductor substrate and thinning a semiconductor device, an acceptor is sometime inactivated or a thermal donor is sometimes generated due to the injected hydrogen ion to thereby result in shift of the threshold value of an MOS transistor to the negative side.

On the other hand, according to the techniques disclosed in Patent Documents 1 to 4, although the threshold value of an MOS transistor can be controlled by arranging an additional gate electrode or a conductive electrode so as to be opposite to the gate electrode of the transistor, the additional gate electrode or the conductive electrode needs to be formed for each transistor and precise alignment is required in the manufacturing process. Consequently, there is a room for improvement in easy manufacture of a semiconductor device equipped with a MOS transistor with controllable threshold value.

In view of the above state of the art, it is an object of the present invention to provide a semiconductor device equipped with a plurality of MOS transistors with controllable threshold values in the same face and easy to manufacture, a manufacturing method thereof, and a display device.

The present inventors have made various investigations concerning a semiconductor device equipped with a plurality of MOS transistors with controllable threshold values in the same face and easy to manufacture, a manufacturing method thereof and a display device, consequently have noted that a technique of arranging conductive electrodes for controlling the threshold values different from the gate electrodes of the MOS transistors, and they have found that the conductive electrodes can be formed with no need of precise alignment by arranging the conductive electrodes extending over at least two MOS transistors and that the above-mentioned problems are solved accordingly. These findings have now led to completion of the present invention.

That is, the present invention is a semiconductor device having a plurality of MOS transistors in the same face each having a structure formed by stacking a semiconductor active layer, a gate insulator, and a gate electrode, wherein the semiconductor device includes: an insulating layer stacked on a side opposite to a gate electrode side of the semiconductor active layer; and a conductive electrode stacked on a side opposite to a semiconductor active layer side of the insulating layer and extending over at least two of the plurality of MOS transistors.

Hereinafter, the present invention will be described more in detail.

The above-mentioned conductive electrode is an electrode formed separately from the gate electrode of an MOS transistor and is enabled to control the threshold value of the MOS transistor by applying a constant voltage to the conductive electrode and thus controlling the conductive electrode independently from the gate electrode. Further, the conductive electrode is formed in such a manner that at least mutually neighboring two MOS transistors are collectively covered so that the threshold values of a plurality of MOS transistors can be collectively controlled. As described, the conductive electrode is not a member to be used as a gate electrode for controlling each MOS transistor but a member to be used for collectively correcting the characteristics of the plurality of MOS transistors. Consequently, since the conductive electrode is formed with no need of precise alignment, the semiconductor device of the present invention can be obtained easily.

As described, the present invention may be a semiconductor device having a plurality of MOS transistors in the same face each having a structure formed by stacking a semiconductor active layer, a gate insulator, and a gate electrode, wherein the semiconductor device further has an insulating layer stacked on a surface opposite to the gate electrode-side surface of the semiconductor active layer and a conductive electrode stacked on a surface opposite to the semiconductor active layer-side surface of the insulating layer and extending over at least two of the plurality of MOS transistors.

In addition, the above-mentioned MOS transistor may be so-called MOSFET (Metal Oxide Semiconductor Field Effect Transistor) or MIS (Metal Insulator Semiconductor). Further, the gate electrode may be a conductor other than metals, for example, polysilicon. Furthermore, the gate insulator may be an oxide or an insulator other than an oxide.

The constitution of the semiconductor device of the present invention may or may not include any other constituent element and is not particularly limited if the above-mentioned constituent elements are indispensably included.

Preferable configurations of the semiconductor device of the present invention will be described in detail below. The respective configurations described below may be combined properly to be used.

The semiconductor device of the present invention is suitable for a device having an integrated circuit transferred onto a supporting substrate. That is, the semiconductor device preferably has a configuration that the semiconductor device has a supporting substrate and an integrated circuit formed on the supporting substrate, wherein the plurality of MOS transistors are MOS transistors formed in the integrated circuit, and the gate electrode, the gate insulator, and the semiconductor active layer are arranged in this order from the supporting substrate side (hereinafter, also referred to as “first configuration”). Consequently, a conductive electrode can be formed easily for the MOS transistors formed in the integrated circuit.

The above-mentioned integrated circuit may be so-called an integrated circuit chip. Further, the number of the MOS transistors formed in the integrated circuit is not particularly limited if it is two or more. That is, the scale of the integrated circuit is not particularly limited and the integrated circuit may be a large scale interation (LSI).

Members other than the integrated circuit may be formed on the supporting substrate and TFT may be formed. Consequently, since a circuit group having capability as high as that of bulk silicon and polysilicon TFT formed on a supporting substrate are allowed to be co-present, the semiconductor device of the present invention can be used preferably for a display device such as system liquid crystal or the like.

The conductive electrode may have a configuration where the conductive electrode covers a PMOS transistor group constituted by a plurality of CMOS transistors. Consequently, the threshold value of the entire circuit including the PMOS transistor group can be precisely controlled. As described, the plurality of MOS transistors may include a plurality of CMOS transistors and the conductive electrode may cover a PMOS transistor group constituted by the plurality of CMOS transistors.

The conductive electrode may have a configuration where the conductive electrode covers an NMOS transistor group constituted by a plurality of NMOS transistors. Consequently, the threshold value of the entire circuit including the NMOS transistor group can be precisely controlled. As described, the plurality of MOS transistors may include a plurality of NMOS transistors and the conductive electrode may cover an NMOS transistor group constituted by the plurality of NMOS transistors.

The conductive electrode may have a configuration where a CMOS transistor group constituted by a plurality of PMOS transistors and an NMOS transistor group constituted by a plurality of NMOS transistors are mutually independently covered with the conductive electrode. Consequently, since it is made possible to apply a different voltage to the conductive electrode between the PMOS transistor group and the NMOS transistor group, the threshold value of the circuit including the respective MOS transistor groups can be precisely and simultaneously controlled. As described, the plurality of MOS transistors may include a plurality of PMOS transistors and a plurality of NMOS transistors, and a CMOS transistor group constituted by the plurality of PMOS transistors and an NMOS transistor group constituted by the plurality of PMOS transistors may be mutually independently covered, with the conductive electrode.

The conductive electrode may have a configuration where the conductive electrode collectively covers all of MOS transistors formed in the same process. Consequently, it is made possible to simultaneously control the threshold values of all of MOS transistors formed in the same process and the effect on the threshold values in the same manufacturing process can be corrected. As described, the conductive electrode may collectively cover all of MOS transistors formed by the same process among the plurality of MOS transistors.

The conductive electrode may have a configuration where the conductive electrode is arranged in each circuit block constituted by a plurality of MOS transistors. Consequently, the threshold values of a plurality of transistors can be controlled in each circuit block. As described, the conductive electrode may be arranged in each circuit block constituted by a plurality of MOS transistors among the plurality of MOS transistors.

The semiconductor device may have a configuration where the semiconductor includes a first wiring and a second wiring,

wherein the first wiring is closer to the supporting substrate than the semiconductor active layer is,

the second wiring is arranged on the side opposite to the semiconductor active layer side of the insulating layer, and

the conductive electrode is arranged in the same layer as the second wiring. Consequently, since the conductive electrode and the second wiring can be formed simultaneously, the manufacturing process can be simplified.

The semiconductor device may have a configuration where the semiconductor device includes a first wiring and a second wiring,

wherein the first wiring is closer to the supporting substrate than the semiconductor active layer is,

the second wiring is arranged on the side opposite to the semiconductor active layer side of the insulating layer, and

the conductive electrode is arranged in a layer lower than the second wiring. Consequently, since the conductive electrode can be arranged further closer to the semiconductor active layer, the effect of controlling the characteristics of the MOS transistors by the conductive electrode can be heightened. Further, since the conductive electrode and the semiconductor active layer are arranged closer to each other, ambient light is efficiently shielded by the conductive electrode. As a result, light leakage current of the MOS transistors can be lowered. In this description, a layer lower than X means a layer that is closer to the supporting substrate than X is.

The semiconductor device may have a configuration where the semiconductor device includes a first wiring and a second wiring,

wherein the first wiring is closer to the supporting substrate than the semiconductor active layer is,

the second wiring is arranged on the side opposite to the semiconductor active layer side of the insulating layer, and

the conductive electrode is arranged in a layer upper than the second wiring. Consequently, the insulating film between the conductive electrode and the semiconductor active layer is easily formed into a thick film and therefore, S values of the MOS transistors can be easily improved. Additionally, in this description, a layer upper than X means that a layer that is further away from the supporting substrate than X is.

The first wiring is preferably a wiring for connecting MOS transistors in a circuit block, that is, a source-drain wiring. On the other hand, the second wiring is preferably a wiring for connecting a circuit block and an outside part of the circuit block. In addition, the second wiring may be a wiring for connecting different circuit blocks to one another formed in the same integrated circuit. Furthermore, the second wring may also be so-called source-drain wiring since the second wiring may be connected electrically with the first wiring.

The semiconductor device may have a configuration where the semiconductor device includes an upper layer wiring arranged in a layer upper than the conductive electrode, wherein the conductive electrode is controlled by the upper layer wiring, but the semiconductor device more preferably has a configuration where the semiconductor device has a lower layer wiring arranged in a layer lower than the conductive electrode, wherein the conductive electrode is controlled by the lower layer wiring. Consequently, the thickness of the semiconductor device can be made thin as compared with that of the semiconductor device having a configuration of controlling the conductive electrode by the upper layer wiring. That is, it is possible to allow the semiconductor device to have a thin profile.

The semiconductor device may have a configuration where the semiconductor device includes a wiring at least partly overlapping with the conductive electrode in a plane view, wherein the conductive electrode is arranged while being electrically insulated and controlled by the wiring. Consequently, since the conductive electrode can be controlled like a floating gate, the threshold values of MOS transistors can be controlled by utilizing the coupling capacity of the conductive electrode and the wiring. Further, a contact hole formation process for connecting the conductive electrode and the wiring can be omitted.

The semiconductor device preferably has a configuration where the conductive electrode covers each channel region of at least two MOS transistors in a plane view. Consequently, the threshold values of MOS transistors can be more reliably controlled by the conductive electrode. As described, the conductive electrode may cover each channel region of at least two of the plurality of MOS transistors in a plane view.

The supporting substrate may be a glass substrate. Consequently, since the supporting substrate may be made transparent, the semiconductor device of the present invention is made preferably usable for a display device such as a liquid crystal display device. In general, since a glass substrate is considerably larger than an integrated circuit chip and an exposure apparatus for a glass substrate is inferior in the alignment precision as compared with an exposure apparatus for an integrated circuit chip, it has been very difficult to carry out patterning of the conductive electrode with highly precise alignment for MOS transistors in an integrated circuit transferred onto the glass substrate. In contrast to this, the semiconductor device of the present invention requires no precise alignment for the patterning of the conductive electrode and therefore, the invention can be employed preferably for the semiconductor device formed on such a glass substrate.

The present invention is also a method for manufacturing the semiconductor device of the invention, the method includes the steps of transferring the integrated circuit containing the plurality of MOS transistors onto the supporting substrate; forming the insulating layer on the semiconductor active layer of the plurality of MOS transistors transferred; and forming the conductive electrode on the insulating layer in such a manner that the conductive electrode extends over at least two of the plurality of MOS transistors transferred. Consequently, the conductive electrode is arranged with no need of precise alignment in the plurality of MOS transistors formed in the integrated circuit. That is, the semiconductor device of the first configuration can be easily manufactured.

As described, the method for manufacturing the semiconductor device of the present invention may be a manufacturing method including the steps of transferring an integrated circuit having a plurality of MOS transistors to a supporting substrate; forming an insulating layer on a semiconductor active layer of the plurality of MOS transistors transferred; and forming a conductive electrode on the insulating layer in such a manner that the conductive electrode extends over at least two of the plurality of MOS transistors transferred.

The method for manufacturing the semiconductor device of the present invention may or may not include other steps and is not particularly limited if the above-mentioned steps are indispensably included.

Preferable aspects of the method for manufacturing the semiconductor device of the present invention will be described in detail below.

The method for manufacturing the semiconductor device may include a step of ion-injecting a hydrogen-containing substance for separation into the plurality of MOS transistors formed in the integrated circuit before the transfer step. As described above, in the case of transferring the integrated circuit and separating a semiconductor substrate and making the semiconductor substrate thin by the smart cut method, the threshold values of the MOS transistors are particularly easily shifted (shifted to the negative side); however the negative shift can be efficiently controlled by the present invention.

The substance for separation is not particularly limited if it can make the semiconductor substrate (preferably a silicon substrate) thin, and it may contain an inert element such as helium (He) and neon (Ne) other than hydrogen.

The present invention is also a display device having the semiconductor device of the invention or the semiconductor device manufactured by the method for manufacturing the semiconductor device of the invention. Consequently, since the semiconductor device having a highly densely integrated circuit excellent in the operation speed can be mounted in the display device, the display device can be allowed to have a thin profile, a small frame region and high functionality.

### EFFECT OF THE INVENTION

It is made possible to arrange the conductive electrode extending over at least two MOS transistors with no need of precise alignment by using the semiconductor device of the present invention. Therefore, a semiconductor device equipped with a plurality of MOS transistors with controllable threshold values in the same face can be easily manufactured.

### BEST MODE FOR CARRYING OUT THE INVENTION

The present invention is mentioned in more detail with reference to drawings showing Embodiments but not limited to only these Embodiments.

### Embodiment 1

Hereinafter, a method for manufacturing the semiconductor device of Embodiment 1 will be described with reference to drawings. FIG. 1-1 and FIG. 1-2 are schematic cross-sectional views showing the method for manufacturing the semiconductor device of Embodiment 1. In this embodiment, a case where MOS transistors to be formed in an integrated circuit are, but not limited to, NMOS transistors will be described, and the MOS transistors may be PMOS transistors and also both of NMOS transistors and PMOS transistors.

As shown in FIG. 1-1(a), each of a plurality of NMOS transistors 30 in Embodiment 1 includes the following constitution formed on a silicon substrate 1 constituted by a single crystal silicon wafer: a semiconductor active layer 7 containing an N-type impurity region 6; a thermal oxidation film 2 covering the silicon substrate 1 and a LOCOS (Local Oxidation of Silicon) oxide film 3 formed in element separation region of the thermal oxidation film 2; a gate oxide film (gate insulator) 4 formed on the thermal oxidation film 2; and a gate electrode 5 formed on the gate oxide film 4 are arranged in this order from the silicon substrate 1 side, and the gate oxide film 4 and the gate electrode 5 are patterned in such a manner that the gate oxide film 4 and the gate electrode 5 overlaps with the channel region of the semiconductor active layer 7.

First, a circuit group is formed on the silicon substrate 1. More specifically, the thermal oxidation film 2 with a thickness of about 30 nm is formed on the surface of the silicon substrate 1 by heat treatment at a temperature of about 1050 to 1150° C. The thermal oxidation film 2 is a film for preventing the surface of the silicon substrate 1 from being polluted in the step of ion-injection of an impurity element and may be formed as described above or may not be formed. Successively, LOCOS oxidation is carried out in an oxygen atmosphere to form the LOCOS oxide film 3 with a thickness of about 200 to 500 nm for element separation. Further successively, in order to adjust the threshold voltage to be a desired value, the semiconductor active layer 7 is formed by ion-injection of an impurity element. In this case, if NMPO transistors are to be formed, ion-injection is carried out using boron (B), a P-type impurity, as the impurity element in a dose of about 1×10¹² to 1×10¹³ cm⁻² by injection energy of about 10 to 50 KeV. Next, the silicon substrate 1 is subjected to heat treatment at a temperature of about 1000° C. in an oxygen atmosphere to form the gate oxide film 4 with a thickness of about 10 to 20 nm. Next, after polysilicon or the like with a thickness of about 300 nm is deposited by CVD (Chemical Vapor Deposition) or the like, patterning in a prescribed form is carried out to form the gate electrode 5. Next, an N-type impurity element is ion-injected in the semiconductor active layer 7 using the gate electrode 5 as a mask to form the N-type impurity region 6. In this case, if NMOS transistors are to be formed, ion-injection is carried out using phosphorus (P) or the like as an N-type impurity in a dose of about 1×10¹³ to 1×10¹⁴ cm⁻² by n injection energy of about 10 to 50 KeV.

Next, as shown in FIG. 1-1(b), a first flattening film 8 and a separation layer 10 are formed. First, after an insulating film such as SiO₂ is formed by CVD or the like so as to cover the entire surface of the silicon substrate 1 on the gate electrode 5 side, the first flattening film 8 with a thickness of about 600 nm is formed by flattening by CMP (Chemical Mechanical Polishing) or the like. Successively, a substance 9 for separation containing hydrogen and at least one kind, of inert elements such as helium (He) and neon (Ne) is ion-injected in the silicon substrate 1 to form the separation layer 10. In this case, if hydrogen is used, ion-injection is carried out in a dose of about 5×10¹⁶ to 1×10¹⁷ cm⁻² by injection energy of about 100 to 200 KeV. In addition, even in a case where a substance 9 for separation containing no hydrogen is ion-injected, it is possible to form the separation layer 10, but from the viewpoint of minimization of the occurrence of defects at the time of ion injection, it is preferable to ion-inject the substance 9 for separation containing hydrogen. Further, as described above, in the case of ion injection of the substance 9 for separation containing hydrogen, occurrence of negative shift of the threshold values can be suppressed particularly efficiently.

Next, as shown in FIG. 1-1(c), a first contact hole 11, a first wiring (a source-drain wiring) 12 for connecting the respective MOS transistors in the same circuit block and a second flattening film 13 are formed. First, the first contact hole 11 penetrating the thermal oxidation film 2 and the first flattening film 8 are formed on the N-type impurity region 6. Successively, a high melting point metal material such as tungsten (W) or molybdenum (Mo) is applied in the first contact hole 11 and on the first flattening film 8 and subjected to patterning to form the first wiring 12. Further successively, after an insulating film such as SiO₂ is formed by CVD or the like so as to cover the entire surface of the silicon substrate 1 on the first wiring 12 side, flattening is carried out by CMP or the like to form the second flattening film 13 with a thickness of about 600 nm. Thereafter, dicing is carried out to obtain an integrated circuit chip 50.

Next, as shown in FIG. 1-1(d), the integrated circuit chip 50 is transferred onto a transparent supporting substrate (glass substrate) 14 made of glass in which the TFT 15 is partway formed. First, after the surfaces of the second flattening film 13 and the supporting substrate 14 are washed with a washing liquid such as SC1, positioning is carried out to stick the integrated circuit chip 50 and the supporting substrate 14 based on such as Van Der Waals force and hydrogen bonding. Successively, the silicon substrate 1 is subjected to heat treatment of about 400 to 600° C., so that the silicon substrate 1 is separated along the separation layer 10 formed by hydrogen injection. Consequently, the integrated circuit chip 50 can be transferred onto the supporting substrate 14.

Next, as shown in FIG. 1-2(e), the separation layer 10 remaining in the second flattening film 13 is removed by etching or the like, the semiconductor active layer 7 and the silicon substrate 1 are further subjected to etching to expose the LOCOS oxide film 3. Consequently, the semiconductor active layer 7 is made thin and the element separation is carried out.

Next, as shown in FIG. 1-2(f), a protective film 16 is formed as an insulating layer to protect the surface of the exposed semiconductor active layer 7 and keep the electric insulation property. More specifically, SiO₂ is deposited by low temperature CVD using TEOS (Tetraethoxysilane) in such a manner that the LOCOS oxide film 3 and the semiconductor active layer 7 are covered to form the protective film 16 with a thickness of about 90 to 120 nm.

Next, as shown in FIG. 1-2(g), a second contact hole 17, a second wiring 18, and a conductive electrode 19 are formed. In addition, the second wiring 18 is a wiring for connecting the respective MOS transistors with an outside part such as an electric power source, bus wiring and another circuit block on the supporting substrate 14. First, the second contact hole 17 penetrating the first flattening film 8, the LOCOS oxide film 3, and the protective film 16 are formed on the first wiring 12 positioned at an end part of the integrated circuit chip 50 (or a circuit block). Successively, a low melting point metal material such as aluminum (Al) is applied in the second contact hole 17 and on the protective film 16 and subjected to patterning to simultaneously form the second wiring 18 and the conductive electrode 19 in the same layer. In this case, the conductive electrode 19 is arranged to extend over the plurality of NMOS 30. Further, the conductive electrode 19 is formed in continuity without disconnection in such a manner that the plurality of NMOS transistors 30 are collectively covered. As described above, according to the steps shown in FIG. 1-1 and FIG. 1-2, a semiconductor device 100a of Embodiment 1 can be manufactured.

As described, in the semiconductor device 100a, the conductive electrode 19 is arranged to extend over the plurality of NMOS transistors 30 in the integrated circuit chip 50, and whereby it is made possible to arrange the conductive electrode 19 with no precise alignment. The threshold values of the plurality of NMOS transistors 30 can be controlled collectively by applying a voltage to this conductive electrode 19 separately to the gate electrode 5. Further, since the second wiring 18 and the conductive electrode 19 can be formed simultaneously by arranging the second wiring 18 and the conductive electrode 19 in the same layer, the step of manufacturing the semiconductor device 100a of this embodiment can be simplified. Further, since the semiconductor device 100a includes the integrated circuit chip 50 and the TFT 15 on the supporting substrate 14, the semiconductor device 100a can be used preferably for application of system liquid crystal or the like by using the TFT 15 as a pixel switching element and controlling the TFT 15 by the integrated circuit chip 50. A film formed by low temperature CVD, that is, the protective film 16, in general, contains a large quantity of fixed charge, and the effect of the fixed charge can be adjusted by the conductive electrode 19.

Hereinafter, modified examples of Embodiment 1 will be described with reference to FIG. 2 and FIG. 3. FIG. 2 and FIG. 3 are schematic cross-sectional views showing the modified examples of the semiconductor device of Embodiment 1.

As shown in FIG. 2, the conductive electrode 19 may be arranged on a protective film 16a formed on the LOCOS oxide film 3 and the semiconductor active layer 7, and the second wiring 18 may be arranged on a protective film 16b formed on the conductive electrode 19 and the protective film 16a. That is, the conductive electrode 19 may be arranged in a layer lower than the second wiring 18. In addition, the protective film 16a and the protective film 16b may be formed in the same conditions as those of the above-mentioned protective film 16.

As described, arrangement of the conductive electrode 19 in a layer lower than the second wiring 18 and arrangement of the conductive electrode 19 further closer to the semiconductor active layer 7 further heighten the effect of controlling the characteristics of the NMOS transistors 30 by the conductive electrode 19. Further, close arrangement of the conductive electrode 19 and the semiconductor active layer 7 effectively shields ambient light by the conductive electrode. As a result, light leakage current of the MOS transistors 30 can be lowered. Furthermore, since a constant interval can be kept between the first wiring 12 and the second wiring 18 by arranging the conductive electrode 19 and the second wiring 18 in different layers and arranging only the conductive electrode 19 in the layer on the supporting substrate 14 side, the parasite capacity between the first wiring 12 and the second wiring 18 can be easily suppressed.

Moreover, as shown in FIG. 3, the second wiring 18 may be arranged on a protective film 16c formed on the LOCOS oxide film 3 and the semiconductor active layer 7 and the conductive electrode 19 may be arranged on a protective film 16d formed on the second wiring 18 and the protective film 16c. That is, the conductive electrode 19 may be arranged in a layer upper than the second wiring 18. In addition, the protective film 16c and the protective film 16d may be formed in the same conditions as those of the above-mentioned protective film 16.

As described, the total thickness of the protective film 16c and protective film 16d can be easily made thicker than the thickness of the gate oxide film 4 by arranging the conductive electrode 19 in a layer upper than the second wiring 18, and S values of the NMOS transistors 30 can be easily improved. In this case, the total thickness of the protective film 16c and protective film 16d is preferable to be 2 to 5 times as thick as the thickness of the gate oxide film 4.

The arrangement place of the wiring for controlling the conductive electrode is not particularly limited and may be an arrangement place shown in FIG. 4. FIG. 4(a) to FIG. 4(d) are schematic cross-sectional views of the semiconductor device of Embodiment 1, showing arrangement examples of the wiring for controlling the conductive electrode. The members supposed to be unnecessary for the description will be omitted.

As shown in FIG. 4(a), the conductive electrode 19 may be arranged while being electrically insulated on the supporting substrate 14 and may be controlled like a floating gate by the second wiring (source-drain wiring) 18 arranged in such a manner that at least a part thereof overlaps with the conductive electrode 19. Consequently, the threshold values of MOS transistors can be controlled by utilizing the coupling capacity of the conductive electrode 19 and the second wiring 18.

As shown in FIG. 4(b), the conductive electrode 19 may be arranged while being electrically insulated on the supporting substrate 14 and may be controlled like a floating gate by a third wiring 22, which is a wiring for controlling a conductive electrode different from the source-drain wiring and is arranged in such a manner that at least a part thereof overlaps with the conductive electrode 19. Consequently, the threshold values of MOS transistors can be controlled by utilizing the coupling capacity of the conductive electrode 19 and the third wiring 22.

Hereinafter, the principle of the control of the threshold values of MOS transistors by utilizing the coupling capacity of the conductive electrode 19 and the second wiring 18, the third wiring 22, or the like, will be described with reference to FIG. 5. FIG. 5 is a schematic view showing the semiconductor device of Embodiment 1 in a case where the conductive electrode is controlled like a floating gate and FIG. 5(a) is a schematic cross-sectional view and FIG. 5(b) is an equivalent circuit. The members supposed to be unnecessary for the description will be omitted.

FIG. 5(a) shows a state where V_{G} (voltage to be applied to the gate electrode 5)=V_{T} (threshold voltage) in a configuration that the conductive electrode 19 is arranged while being electrically insulated on the supporting substrate 14 and the wiring 23, which is the second wiring 18, the third wiring 22, or the like, is arranged in such a manner that at least apart thereof overlaps with the conductive electrode 19. If the voltage V_{SUB} to be applied to the wiring 23 is changed by ΔV_{SUB} the equivalent circuit including the alteration ΔV_{X} of the potential of the interface between the semiconductor active layer 7 and the gate insulator 4 and the alteration ΔV_{T} of the threshold voltage is expressed as FIG. 5(b). In this case, the capacity C_{BACK} attributed to the conductive electrode 19 can be calculated according to the following expression (1) as a synthesized capacity of the capacity Cₐₚ₁ between the wiring 23 and the conductive electrode 19 and the capacity Cₐₚ₂ between the semiconductor active layer 7 and the conductive electrode 19.

C_{BACK}=(Cₐₚ₁·Cₐₚ₂)/(Cₐₚ₁+Cₐₚ₂) (1)

If the capacity generated between the gate electrode 5 and the semiconductor active layer 7 is defined as C_{OX}, the following expression (2) is established based on the law of conservation of charge.

C_{OX}(ΔV_{T}−ΔV_{X})=C_{BACK}(ΔV_{X}−ΔV_{SUB}) (2)

Substitution of the expression (1) into the expression (2) leads to the following expression (3).

ΔV_{T}=(C_{OX}+C_{BACK})ΔV_{X}−C_{BACK}·ΔV_{SUB})/C_{OX} (3)

Herein, if V_{G}=V_{T}, ΔVₓ scarcely changes and therefore, ΔVₓ is regarded as zero. Consequently, the alteration of the threshold voltage V_{T} to the voltage V_{SUB} to be applied to the wiring 23 is expressed as the following expression (4).

ΔV_{T}/ΔV_{SUB}=dV_{T}/dV_{SUB}=−C_{BACK}/C_{OX} (4)

As expressed by the expression (4), the alteration of the threshold voltage V_{T} is determined based on C_{BACK}. That is, the threshold values of MOS transistors can be controlled to be desired values by properly adjusting the distance between the conductive electrode 19 and the wiring 23 and the area of the region where the conductive electrode 19 and the wiring 23 are overlapped each other in a plane view.

On the other hand, the conductive electrode 19 may be connected directly with the third wiring 22 on the supporting substrate 14 as shown in FIG. 4(c) or may be connected directly with the first wiring 12 on the supporting substrate 14 as shown in FIG. 4(d).

As described along with FIG. 4(a) to FIG. 4(d), the thickness of the semiconductor device can be made thin by controlling the conductive electrode 19 through the lower layer wiring (e.g., the first wiring 12 or the third wiring 22) arranged lower than the conductive electrode 19 as compared with a configuration of controlling the conductive electrode by the upper layer wiring. That is, it is possible to allow the semiconductor device to have a thin profile.

### Embodiment 2

Hereinafter, a semiconductor device of Embodiment 2 will be described with reference to FIG. 6. FIG. 6 is a schematic view showing the semiconductor device of Embodiment 2 and FIG. 6(a) is a schematic cross-sectional view thereof and FIG. 6(b) and FIG. 6(c) are each schematic plane views thereof. A manufacturing method of the semiconductor device of Embodiment 2 is the same as that of Embodiment 1 and therefore, the description is omitted and different points in the constitution will be described. The members supposed to be unnecessary for the description will be omitted.

As shown in FIG. 6(a) and FIG. 6(b), a semiconductor device 100d of Embodiment 2 includes the supporting substrate 14, a semiconductor chip (integrated circuit chip) including a PMOS transistor group 41 constituted by a plurality of PMOS transistors 40 and an NMOS transistor group 31 constituted by a plurality of NMOS transistors 30 and transferred onto the supporting substrate 14, a conductive electrode 20a collectively covering the PMOS transistor group 41, and a conductive electrode 20b collectively covering the NMOS transistor group 31. As described, the conductive electrode 20a and the conductive electrode 20b are mutually independently arranged. Consequently, as shown in FIG. 6(b), since different voltage V_{A} and voltage V_{B} can be applied to the conductive electrode 20a and the conductive electrode 20b, respectively, the threshold values of the PMOS transistor group 41 and the NMOS transistor group 31 can be precisely and simultaneously controlled. In addition, the conductive electrode may be arranged in such a manner that either one of the PMOS transistor group 41 and the NMOS transistor group 31 is collectively covered.

Further, the number of the PMOS transistors 40 covered by the conductive electrode 20a and the number of the NMOS transistors 30 covered by the conductive electrode 20b may be two or more and as shown in FIG. 6(c), the conductive electrode 20a may be arranged to cover the PMOS transistor group 41 constituted by two PMOS transistors 40 and the conductive electrode 20b may be arranged to cover the NMOS transistor group 31 constituted by two NMOS transistors 30. In addition, the number of the PMOS transistors 40 covered by the conductive electrode 20a may be the same or different from the number of the NMOS transistors 30 covered by the conductive electrode 20b.

### Embodiment 3

Hereinafter, a semiconductor device of Embodiment 3 will be described with reference to FIG. 7. FIG. 7 is a schematic view showing the semiconductor device of Embodiment 3 and FIG. 7(a) is a schematic cross-sectional view thereof and FIG. 7(b) is a schematic plane view thereof. A manufacturing method of the semiconductor device of Embodiment 3 is the same as that of Embodiment 1 and therefore, the description is omitted and different points in the configuration will be described. The members supposed to be unnecessary for the description will be omitted.

As shown in FIG. 7(a) and FIG. 7(b), a semiconductor device 100e of Embodiment 3 includes the supporting substrate 14, a semiconductor chip (integrated circuit chip) including the PHOS transistor group 41 constituted by the plurality of PMOS transistors 40 and the NMOS transistor group 31 constituted by the plurality of NMOS transistors 30 and transferred onto the supporting substrate 14, a conductive electrode 21 collectively covering the PMOS transistor group 41 and the NMOS transistor group 31. Consequently, as shown in FIG. 7(b), since the conductive electrode 21 can apply the same voltage V_{C} to the PMOS transistor group 41 and the NMOS transistor group 31, the effect on the threshold value of the entire circuit group formed in the integrated circuit chip by the manufacturing process can be corrected.

### Embodiment 4

Hereinafter, a semiconductor device of Embodiment 4 will be described with reference to FIG. 8. FIG. 8 is a schematic plane view showing the semiconductor device of Embodiment 4. A manufacturing method of the semiconductor device of Embodiment 4 is the same as that of Embodiment 1 and therefore, the description is omitted and different points in the configuration will be described. The members supposed to be unnecessary for the description will be omitted.

As shown in FIG. 8, a semiconductor device 100f of Embodiment 4 includes a supporting substrate, a semiconductor chip (integrated circuit chip) including a plurality of circuit blocks 70a, 70b, 70c, and 70d each constituted by a plurality of MOS transistors 60 and transferred onto the supporting substrate, and conductive electrodes 24a, 24b, 24c, and 24d arranged in each circuit block. With such a configuration, the threshold values of the plurality of MOS transistors 60 can be collectively controlled in each circuit block. In addition, the circuit blocks 70a, 70b, 70c, and 70d are not particularly limited and may be a gate driver, a source driver, a power source circuit, an optical sensor circuit, a temperature sensor circuit, a level shifter and the like. Further, the circuit blocks 70a, 70b, 70c, and 70d may mutually independently include PMOS transistors and NMOS transistors, and it is preferable that the circuit blocks include either PMOS transistors or NMOS transistors.

The semiconductor device of the present invention is described in detail with reference to Embodiments 1 to 4, and the above-mentioned embodiments may be combined properly. FIG. 9 and FIG. 10(a) and FIG. 10(b) are schematic plane views showing the semiconductor devices of the other embodiments of the invention. Manufacturing methods thereof are the same as that of Embodiment 1 and therefore, the description is omitted and different points in the configuration will be described. The members supposed to be unnecessary for the description will be omitted.

As shown in FIG. 9, with respect to the semiconductor device of the present invention, a conductive electrode 25a collectively covering the PMOS transistor group 41 formed in the integrated circuit chip, a conductive electrode 25b collectively covering the NMOS transistor group 31, and a conductive electrode 25c collectively covering a specified circuit block 71 may be mutually independently arranged.

Further, as shown in FIG. 10(a), with respect to the semiconductor device of the present invention, the conductive electrode 26 may be arranged to extend over a plurality of TFT (TFT circuits) 15a formed on the supporting substrate. In this case, for example, the configuration may be provided by stacking a conductive electrode, an insulating layer (base layer), a semiconductor active layer, a gate insulator, and a gate electrode in this order on the supporting substrate. Furthermore, as shown in FIG. 10(b), the TFT (TFT circuits) 15a in which the conductive electrode 26 is arranged is preferably a TFT (TFT circuits) constituting peripheral driver circuits 82 in system liquid crystal including a pixel region 81 and the peripheral driver circuits 82 formed on the same supporting substrate 14.

The present application claims priority to Patent Application No. 2008-6168 filed in Japan on Jan. 15, 2008 under the Paris Convention and provisions of national law in a designated State, the entire contents of which are hereby incorporated by reference.

### BRIEF DESCRIPTION OF THE DRAWINGS

FIG. 1-1(a) to FIG. 1-1(d) are schematic cross-sectional views showing a method of manufacturing the semiconductor device of Embodiment 1.

FIG. 1-2(e) to FIG. 1-2(g) are schematic cross-sectional views showing a method of manufacturing the semiconductor device of Embodiment 1.

FIG. 2 is a schematic cross-sectional view showing a modified example of the semiconductor device of Embodiment 1.

FIG. 3 is a schematic cross-sectional view showing a modified example of the semiconductor device of Embodiment 1.

FIG. 4(a) to FIG. 4(d) are schematic cross-sectional views of the semiconductor device of Embodiment 1, showing arrangement examples of a wiring for controlling a conductive electrode.

FIG. 5 is a schematic view showing the semiconductor device of Embodiment 1 in a case where a conductive electrode is controlled like a floating gate.

FIG. 5(a) is a schematic cross-sectional view thereof.

FIG. 5(b) is an equivalent circuit.

FIG. 6 is a schematic view showing the semiconductor device of Embodiment 2.

FIG. 6(a) is a schematic cross-sectional view thereof.

FIG. 6(b) and FIG. 6(c) are each schematic plane views thereof.

FIG. 7 is a schematic view showing the semiconductor device of Embodiment 3.

FIG. 7(a) is a schematic cross-sectional view thereof.

FIG. 7(b) is a schematic plane view thereof.

FIG. 8 is a schematic plane view showing the semiconductor device of Embodiment 4.

FIG. 9 is a schematic plane view showing the semiconductor device of another embodiment of the present invention.

FIG. 10(a) and FIG. 10(b) are schematic plane views showing the semiconductor device of yet another embodiment of the present invention.

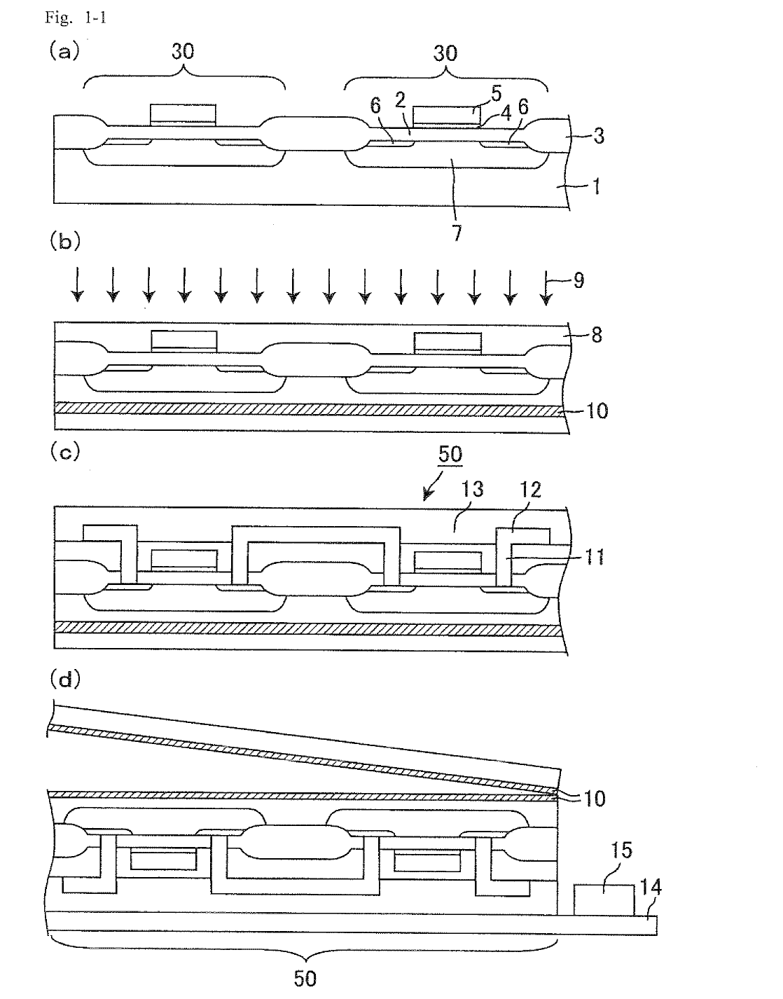

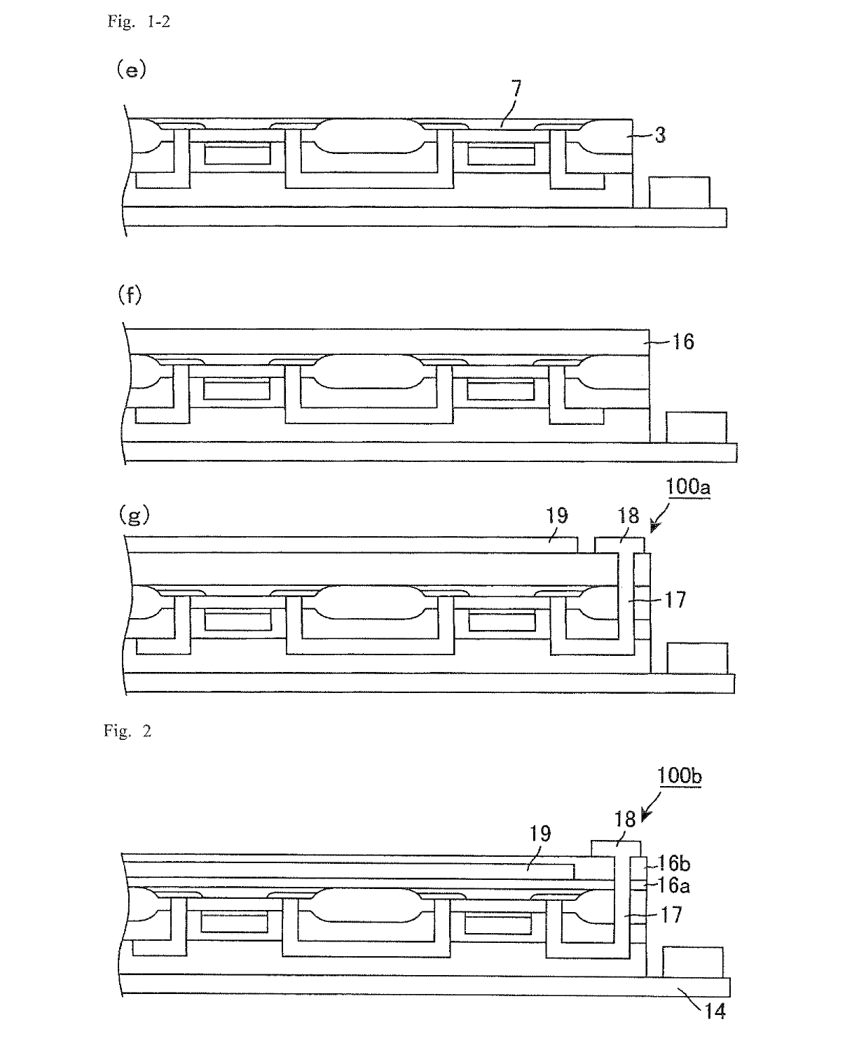

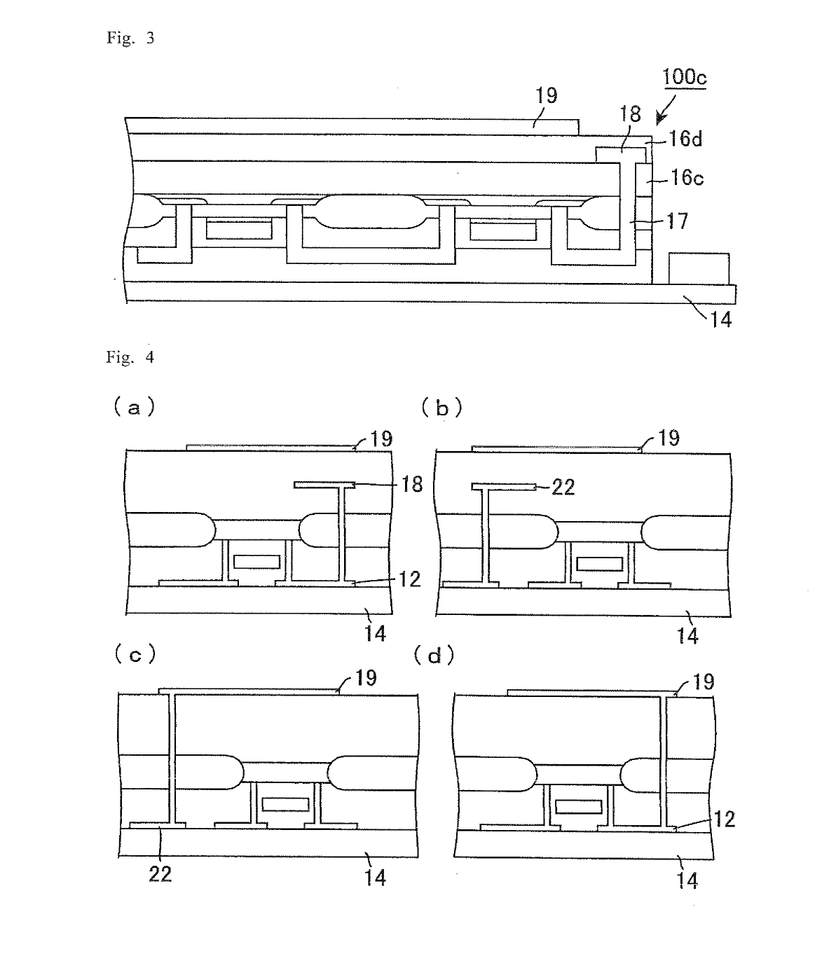

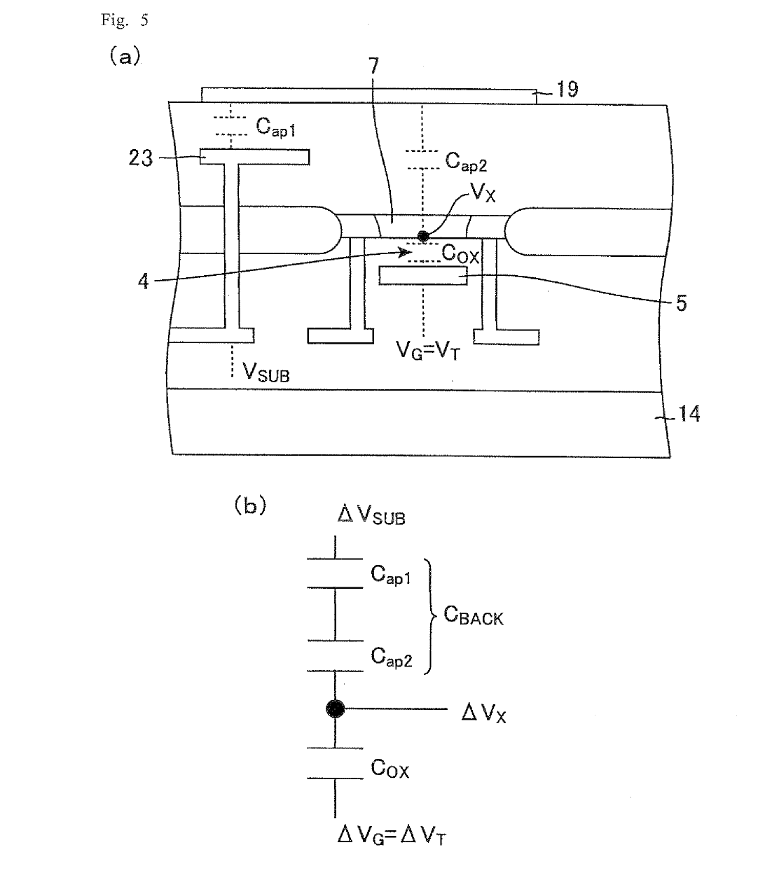

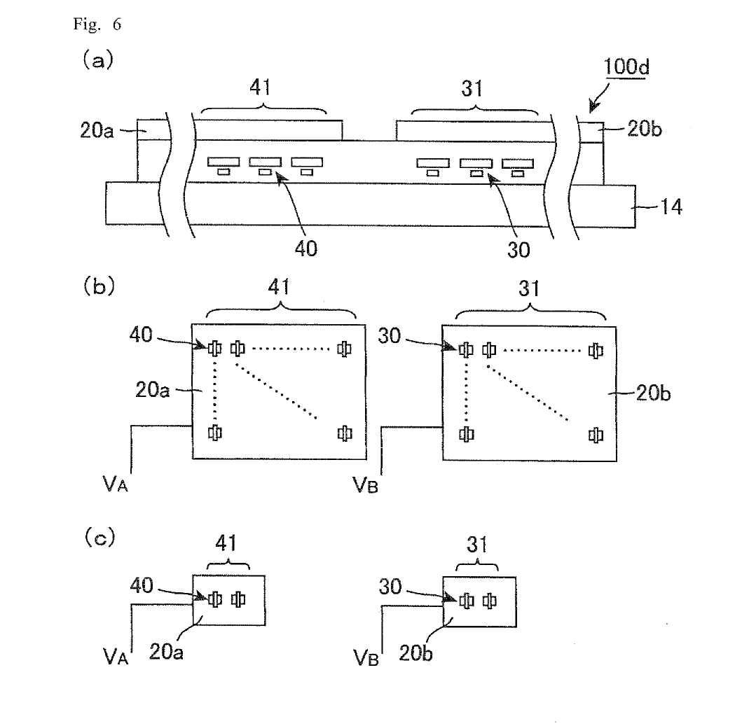

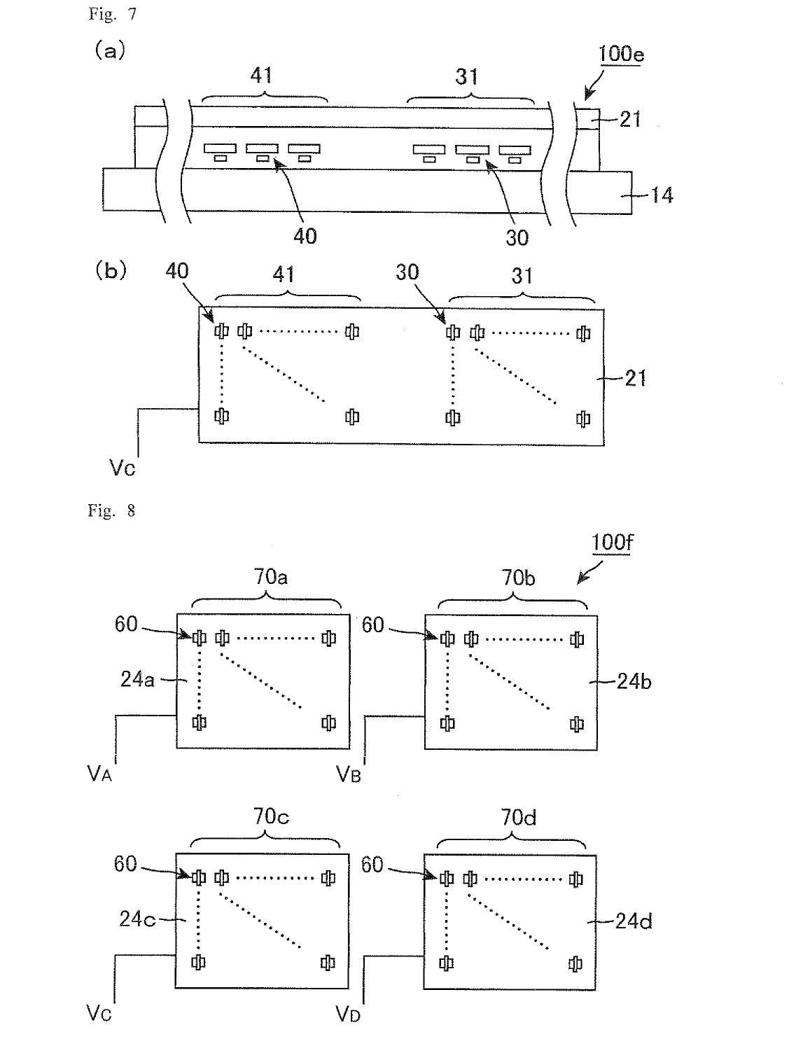

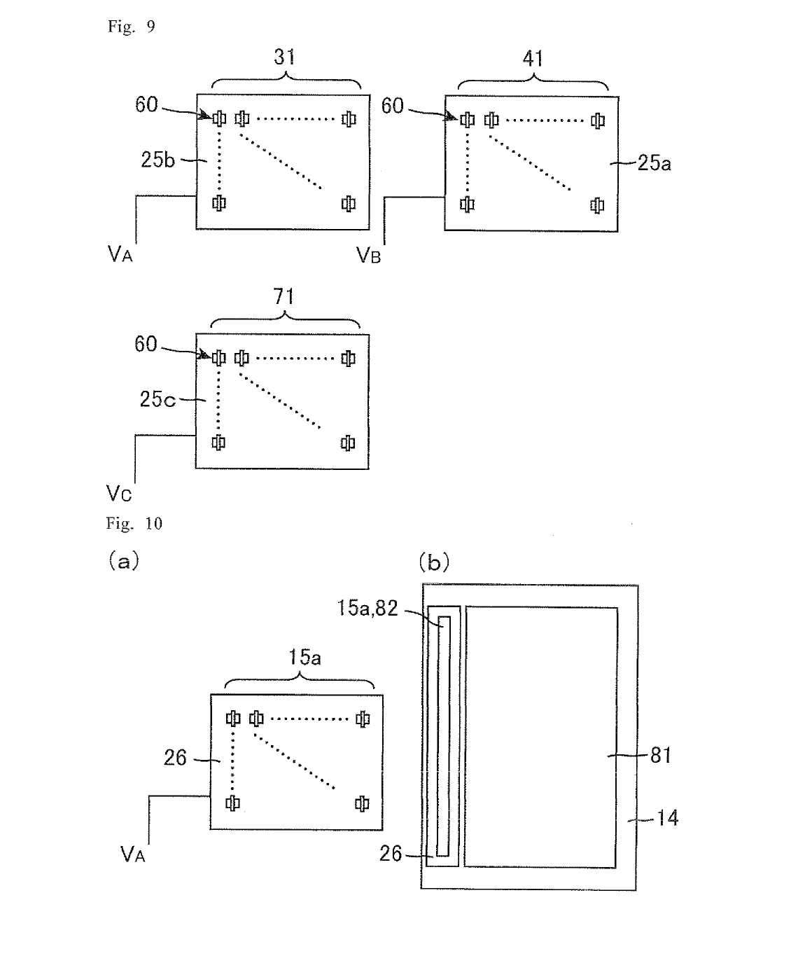

### EXPLANATION OF SYMBOLS

100a, 100b, 100c, 100d, 100e, and 100f: Semiconductor device
1: Silicon substrate
2: Thermal oxidation film
3: LOCOS oxide film
4: Gate oxide film (gate insulator)
5: Gate electrode
6: N-type impurity region
7: Semiconductor active layer
8: First flattening film
9: Substance for separation
10: Separation layer
11: First contact hole
12: First wiring (source-drain wiring)
13: Second flattening film
14: Supporting substrate (glass substrate)
15: TFT
15a: TFT (TFT circuit)
16, 16a, 16b, 16c, and 16d: Protective film (insulating layer)
17: Second contact hole
18: Second wiring (source-drain wiring)
19, 20a, 20b, 21, 24a, 24b, 24c, 24d, 25a, 25b, 25c, and 26: Conductive electrode
22: Third wiring
23: Wiring
30: NMOS transistor
31: NMOS transistor group
40: PMOS transistor
41: PMOS transistor group
50: Integrated circuit chip
60: MOS transistor
70a, 70b, 70c, 70d, and 71: Circuit block
81: Pixel region
82: Peripheral driver circuit

1. A semiconductor device comprising a plurality of MOS transistors in the same face each having a structure formed by stacking a semiconductor active layer, a gate insulator, and a gate electrode,
wherein the semiconductor device includes:
an insulating layer stacked on a side opposite to a gate electrode side of the semiconductor active layer; and
a conductive electrode stacked on a side opposite to a semiconductor active layer side of the insulating layer and extending over at least two of the plurality of MOS transistors.

2. The semiconductor device according to claim 1, comprising a supporting substrate and an integrated circuit formed on the supporting substrate,
wherein the plurality of MOS transistors are MOS transistors formed in the integrated circuit, and
the gate electrode, the gate insulator and the semiconductor active layer are arranged in this order from the supporting substrate side.

3. The semiconductor device according to claim 1,
wherein the plurality of MOS transistors include a plurality of PMOS transistors, and
the conductive electrode covers a PMOS transistor group constituted by the plurality of PMOS transistors.

4. The semiconductor device according to claim 1,
wherein the plurality of MOS transistors include a plurality of NMOS transistors, and
the conductive electrode covers an NMOS transistor group constituted by the plurality of NMOS transistors.

5. The semiconductor device according to claim 1,
wherein the plurality of MOS transistors include a plurality of PMOS transistors and a plurality of NMOS transistors, and
a PMOS transistor group constituted by the plurality of PMOS transistors and an NMOS transistor group constituted by the plurality of NMOS transistors are mutually independently covered with the conductive electrode.

6. The semiconductor device according to claim 1,
wherein the conductive electrode collectively covers all of MOS transistors formed in the same process among the plurality of MOS transistors.

7. The semiconductor device according to claim 1,
wherein the conductive electrode is arranged in each circuit block constituted by a plurality of MOS transistors among the plurality of MOS transistors.

8. The semiconductor device according to claim 2,
comprising a first wiring and a second wiring,
wherein the first wiring is closer to the supporting substrate than the semiconductor active layer is,
the second wiring is arranged on the side opposite to the semiconductor active layer side of the insulating layer, and
the conductive electrode is arranged in the same layer as the second wiring.

9. The semiconductor device according to claim 2,
comprising a first wiring and a second wiring,
wherein the first wiring is closer to the supporting substrate than the semiconductor active layer is,
the second wiring is arranged on the side opposite to the semiconductor active layer side of the insulating layer, and
the conductive electrode is arranged in a layer lower than the second wiring.

10. The semiconductor device according to claim 2,
comprising a first wiring and a second wiring,
wherein the first wiring is closer to the supporting substrate than the semiconductor active layer is,
the second wiring is arranged on the side opposite to the semiconductor active layer side of the insulating layer, and
the conductive electrode is arranged in a layer upper than the second wiring.

11. The semiconductor device according to claim 2, comprising a lower layer wiring arranged in a layer lower than the conductive electrode,
wherein the conductive electrode is controlled by the lower layer wiring.

12. The semiconductor device according to claim 1, comprising a wiring at least partly overlapping with the conductive electrode in a plane view,
wherein the conductive electrode is arranged while being electrically insulated and controlled by the wiring.

13. The semiconductor device according to claim 1,
wherein the conductive electrode covers each channel region of at least two of the plurality of MOS transistors in a plane view.

14. The semiconductor device according to claim 2,
wherein the supporting substrate is a glass substrate.

15. A method for manufacturing the semiconductor device according to claim 2,
comprising the steps of:
transferring the integrated circuit containing the plurality of MOS transistors onto the supporting substrate;
forming the insulating layer on the semiconductor active layer of the plurality of MOS transistors transferred; and
forming the conductive electrode on the insulating layer in such a manner that the conductive electrode extends over at least two of the plurality of MOS transistors transferred.

16. The method for manufacturing the semiconductor device according to claim 15,
further comprising a step of ion-injecting a hydrogen-containing substance for separation into the plurality of MOS transistors formed in the integrated circuit before the transfer step.

17. A display device comprising the semiconductor device according to claim 1.

18. A display device comprising a semiconductor device manufactured by the method for manufacturing the semiconductor device according to claim 15.
